(19) United States
(12) Patent Application Publication
(10) Pub. No.: US 2006/0280859 A1
(43) Pub. Date: Dec. 14, 2006

(54) Manufacturing method of an organic electroluminescent device and an organic electroluminescent device

(76) Inventors: Takahisa Shimizu, Tokyo (JP); Kenichi Oota, Tokyo (JP)

Correspondence Address: SQUIRE, SANDERS & DEMPSEY L.L.P., 1 MARITIME PLAZA, SUITE 300, SAN FRANCISCO, CA, 94111, US

(21) Appl. No.: 11/438,786

(22) Filed: May 22, 2006

(30) Foreign Application Priority Data
Jun. 10, 2005 (JP) 2005-170597

(51) Int. Cl. B05D 5/12; B05D 5/00

(52) U.S. Cl. 427/66; 427/258

(57) ABSTRACT

By reason of a manufacture cost cut, the following method to produce plural organic electroluminescent device from a large-scale substrate was invented. A manufacturing method of organic electroluminescent device comprised of a substrate, first electrode on the substrate, partition wall between the first electrodes, organic luminous media layer including organic luminous layer on the first electrode and second layer which faces the first electrode, wherein the organic luminous media layer is sandwiched between the first and the second electrode, the method comprising: preparing ink which material for at least one organic luminous media layer is dissolved in solvent, forming organic luminous media layer by printing the ink on every divided plural domains of the substrate.

### CROSS REFERENCE

This application claims priority to Japanese application number 2005-170597, filed on Jun. 10, 2005, which is incorporated by reference.

### BACKGROUND OF THE INVENTION

1. Field of the Invention

This invention is related to a process of production of an organic electroluminescent device. Organic luminescent ink which dissolved organic luminescent material in a solvent is used, and an organic luminous layer is formed by a printing method. Especially, the present invention is related to the manufacturing method how the printing method is relief printing method.

2. Description of the Related Art

In late years development of products of flat panel display (following FPD) represented by a liquid crystal display device (following LCD) is remarkable.

LCD especially is applied to wide applications such as small view finder, a mobile telephone, medium-sized notebook PC, monitoring, large-scale TV.

In production of LCD, a lot of panel is made from a large-scale mother glass. Therefore, production efficiency improves. Therefore, feeding of LCD panel of low cost is enabled.

In early stage of production of LCD, the substrate size was 300 mm*350 mm. The production line that substrate size is 1,500 mm*1,800 mm is operated now.

Reduction of a manufacture cost by this upsizing contributes to expansion of market of LCD.

On the other hand, as FPD in place of LCD, a technology development of organic electroluminescent device is remarkable.

Organic electroluminescent device is display device emitting light by oneself. In organic electroluminescent device, superior display is achieved.

In addition, LCD needs a backlight as light source, a color filter to display color and various optics film such as a polarizing plate or a phase difference plate. On the other hand, organic electroluminescent device does not need these member at all.

It is thought that organic electroluminescent device can be superior to LCD in aspects of supply of member and cost.

In organic electroluminescent device, the minute display which a monitor and TV require is enabled same as LCD by applying active matrix driving with the use of thin film transistor. Thin film transistor is written down with TFT.

In present state of LCD, two kinds of TFT which uses amorphous silicon as semiconductor or uses a low temperature polySi as semiconductor are mass-produced. Amorphous silicon is written down with a-Si. A low temperature polySi is written down with LTPS.

In a production line of a-Si type TFT, the glass that size is 1,500 mm*1,800 mm is already used. In the LTPS type TFT that upsizing was difficult, the glass substrate that size is 730 mm*920 mm is already used.

Both of a-Si and LTPS can be used as TFT of active matrix driving of organic electroluminescent device. Thus, a production line of TFT of the present LCD can be just used as a production line of TFT of organic electroluminescence.

In other words, in building of a production line of organic electroluminescence, new plant and equipment investment is unnecessary by use of existing TFT line. Even more particularly, a new technology development in upsizing is unnecessary.

Therefore, a slash of an initial investment cost is possible.

On the other hand, in organic electroluminescent device, methods to form organic luminous layer by means of dry method such as evaporation method to use low molecular luminescent material are established. And organic electroluminescent device is mass-produced by the above described method.

However, evaporation method needs metal masking in patterning. Upsizing of this metal mask does not advance. Size of the present metal mask which can be produced is 500 mm square at the maximum.

On the other hand, the formation of thin film by wet method is tried recently. This method is explained below.

A polymeric material is used as organic luminescent material. Ink is made by means of dissolving organic luminescent material with solvent. By this ink, thin film is formed. As wet method for thin film formation, wet coating method such as spin coat method, bar coat method, extrusion coat method, dip coat method or printing method such as offset printing or relief printing method are exemplified.

However, the following pattern formation is difficult by wet coating method such as spin coat methods, bar coat method, extrusion coat method, dip coat method:

the formation of pattern of high accuracy; and

application of organic luminescent ink of three colors (RGB) (Three colors of organic luminescent ink is separated.).

It is thought that it is more effective to form thin film by means of a printing method which is good at separated application and patterning.

It is often that organic electroluminescent device uses a glass substrate as a substrate. Thus, a method to use metal hard printing plate such as gravure printing methods is unsuitable. Offset printing to use rubber blanket having elasticity and relief printing method to use rubber printing plate and photosensitive resin printing plate having elasticity are suitable. As attempt by these printing methods, a method (Japanese Patent Laid-Open No. 2001-93668 Official Gazette) by offset printing and a method (Japanese Patent Laid-Open No. 2001-155858 Official Gazette) by relief printing are really proposed.

By reason of a manufacture cost cut, a method to produce plural organic electroluminescent device from a large-scale substrate is examined.

In addition, high printing accuracy is required for pattern position matching with an electrode substrate (active matrix driving, TFT substrate) to realize minute matrix display such as a monitor and a TV Matching accuracy of pattern of plus or minus 20 μm is necessary to realize a display unit of VGA (Videographicsarray: graphic display of 640*480 dots) class in organic electroluminescent device.

When organic luminous layer is formed in one printing, printing accuracy of existing relief printing and offset printing is plus or minus 20 μm for total pitch accuracy between both ends of 500 mm square substrate.

Resin printing plate used for relief printing and blanket used for offset printing transform. As sizes of plastic plate and blanket become large, distorsions by modifications of plastic plate and blanket become remarkable. And modifications of plastic plate and blanket cause degradation of pitch accuracy of printed pattern.

Due to the above reason, when organic luminous layer is formed by printing with the use of organic luminescent ink, substrate size cannot be raised. According to the present invention, for example, it is aimed at providing a formation method of organic luminous layer by printing on a large-scale substrate which is larger than 500 mm square.

### SUMMARY OF THE INVENTION

By reason of a manufacture cost cut, the following method to produce plural organic electroluminescent device from a large-scale substrate was invented.

A manufacturing method of organic electroluminescent device comprised of a substrate, first electrode on the substrate, partition wall between the first electrodes, organic luminous media layer including organic luminous layer on the first electrode and second layer which faces the first electrode, wherein the organic luminous media layer is sandwiched between the first and the second electrode, the method comprising: preparing ink which material for at least one organic luminous media layer is dissolved in solvent, forming organic luminous media layer by printing the ink on every divided plural domains of the substrate.

According to the current invention, when a lot of organic electroluminescent device is formed in a large-scale substrate, without influence of modification of plastic plate and blanket, printing of high accuracy is possible.

### BRIEF DESCRIPTION OF DRAWINGS

FIG. 1 shows illustration cross figure of organic electroluminescent device of the present invention.

FIG. 2 shows illustration cross figure of a substrate of active matrix method of the present invention.

FIG. 3 shows a schematic illustration of relief printing device about the present invention.

FIG. 4 shows a profile plane view of a substrate.

FIG. 5 shows a profile plane view of relief printing plate used for printing to a substrate of FIG. 4.

FIG. 6 shows a figure of ITO pattern in an organic electroluminescent display unit of the present invention.

FIG. 7 shows a figure of pattern of cathode comprising MgAg in an organic electroluminescent display unit of the present invention.

### DESCRIPTION OF THE PREFERRED EMBODIMENT

An embodiment of the present invention is explained. In addition, the present invention is not limited to this.

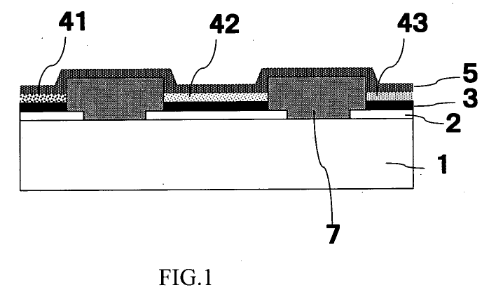

Organic electroluminescent device of the present invention is explained. Illustration cross figure of organic electroluminescent device of the present invention is shown in FIG. 1.

In FIG. 1, pattern-shaped first electrode 2 is formed on substrate 1. In the case of passive matrix method, this first electrode 2 is stripe-shaped pattern. In the case of active matrix method, the first electrode 2 is pattern formed by every pixel.

As a driving method of organic electroluminescent device, passive matrix method and active matrix method are exemplified. Organic electroluminescent device of the present invention can be applied to either an organic electroluminescent device of passive matrix method or organic electroluminescent device of active matrix method.

Passive matrix method is explained. Stripe-shaped electrodes are opposed to be perpendicular. The intersection point emits light.

Active matrix method is explained. So-called thin film transistor (TFT) substrate that transistor is formed at every pixel is used. Every pixel emits light independently.

And partition wall 7 is formed between patternized first electrodes 2. It is preferable for partition wall to be formed to cover the first electrode end. A short-circuit between the first electrode and the second electrode can be prevented by covering the first electrode edge. In the case of an organic electroluminescent device of passive matrix type, partition wall is formed in the shape of stripe. In the case of an organic electroluminescent device of active matrix type, partition wall is formed in the shape of a grating.

An organic luminescent media layer including organic luminous layer is formed in the first electrode partitioned off by partition wall 7. The organic luminescent media layer is a stacked layer having layers such as a hole injection layer, a hole transport layer, an electron blocking layer, an electron transport layer and an electron injection layer besides organic luminous layer.

In FIG. 1, a hole transport layer 3, organic luminous layer (41, 42, 43) are comprised on the first electrode 2. As for the organic luminous layer, there are patterns of red (R) organic luminous layer 41, green (G) organic luminous layer 42 and blue (B) organic luminous layer 43. The second electrode 5 is placed over organic luminescent media layer. The first electrode 2 faces with the second electrode 5. Stripe-shaped second electrode 5 comprises to be perpendicular to stripe-shaped first electrode in the case of passive matrix type. In the case of active matrix type, second electrode 5 is formed on a whole area of an organic electroluminescent device.

Furthermore, a whole area of a pixel is sealed to prevent external moisture and oxygen from entering first electrode, the organic luminescent media layer including organic luminous layer and second electrode. About sealing, it is not illustrated.

A description is now made of a manufacturing method of organic electroluminescent device of the present invention.

A substrate having insulating property can be used as a substrate. In the case of organic electroluminescent device of bottom emission method, it is necessary to use a clear substrate.

By way of example only, a glass substrate and quartz substrate can be used. In addition, plastic film and sheet such as polypropylene, polyether sulfone, polycarbonate, cyclo olefin polymers, polyarylate, polyamide, polymethyl methacrylate, poly ethylene terephthalate and polyethylenenaphthalate can be used. Metallic oxide thin film, metal fluoride thin film, metal nitride thin film, metal oxynitriding membrane thin film or macromolecule resin film may be formed on plastic film or sheet to prevent moisture from entering the organic luminescent media layer.

In addition, it is preferable for a substrate to be heated beforehand. Moisture adsorbed in internal and surface of a substrate is reduced by heating. In addition, depending on material laminated on a substrate, surface of a substrate may be processed by processing such as ultrasonic wave rinse, corona discharge treatment, plasma treatment and UV ozonization for improvement of adhesion.

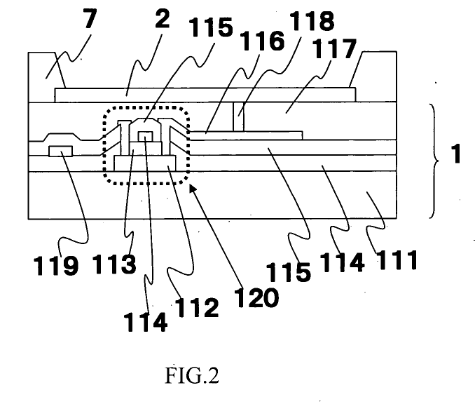

In addition, thin film transistor (TFT) is formed on a substrate, and a substrate for organic electroluminescent device of active matrix method can be made. Illustration cross figure of an example of a substrate of active matrix method of the present invention is shown in FIG. 2. On TFT 120, planarizing layer 117 is formed. A bottom electrode (the first electrode 2) of organic electroluminescent device is comprised on planarizing layer 117. Contact hole 118 is installed in planarizing layer 117. The bottom electrode is electrically connected to TFT by means of contact hole, 118. Due to such a constitution, superior electrical insulating property can be achieved between TFT and organic electroluminescent device. Insulating film between layers 115 is necessary. In FIG. 2, deta line 119 is also illustrated.

TFT 120 and the upward organic electroluminescent device are supported with support medium 111. Support medium 111 should be superior in mechanical intensity and dimensional stability. Materials exemplified as material of a substrate can be used as material of support medium 111.

For thin film transistor 120 in a support medium, well-known thin film transistor can be used. Thin film transistor comprising the active layer that a source/drain region and a channel area are formed, the gate insulator and the gate electrode is exemplified. Configuration of thin film transistor is not limited especially. By way of example only, staggered type, reverse staggered type, top gate type and coplanar type can be used.

Active layer 112 is not limited especially. By way of example only, it can be formed by inorganic semiconductor material such as amorphia Si, polycrystalline silicon, crystallite Si, cadmium selenide or organic. semiconductor material such as thiophene oligomer, poly(phenylene vinylene)

These active layers are made by the following methods.

1. A method to do ion doping after having laminated amorphous silicon by plasma CVD technique.

2. A method comprising the following process. Amorphous silicon is formed by LPCVD method using SiH4 gas. By means of crystallization of amorphous silicon by solid phase epitaxy, a polySi is obtained. Ion doping is done by ion implantation method.

3. A low temperature processing method comprising the following process.

Amorphous silicon is formed. By way of example only, Si₂H₆ gas is used, and amorphous silicon is formed by LPCVD method. Amorphous silicon is formed by PECVD method by means of SiH₄ gas. It is annealed by laser such as excimer lasers. A polySi is obtained by crystallization of amorphous silicon. Ion doping is done by ion doping method.

4. A high temperature processing method comprising the following process. A polySi is laminated by low pressure CVD method or LPCVD method. Thermal oxidation is done in more than 1,000 degrees Celsius, and gate insulator is formed. Thereupon, gate electrode 114 of an n+ polySi is formed. Ion doping is done by ion implantation method.

For gate insulator 113, conventional gate insulator can be used. By way of example only, SiO₂ formed by PECVD method or LPCVD method and SiO₂ made by thermal oxidation of polysilicon film can be used.

For gate electrode 114, conventional gate electrode can be used. By way of example only, metal such as aluminum, copper, refractory metal such as titanium, tantalum, tungsten, a polySi, silicide of refractory metal and polycide can be used.

For configuration of thin film transistor 120, a single gate structure, a double gate structure, multiple gating configuration having gate electrodes more than 3 are exemplified. In addition, LDD configuration, offset configuration may be provided. Even more particularly, thin film transistors more than 2 may be placed all over one pixel.

It is necessary for a display unit of the present invention to be connected to so that thin film transistor functions as a switching element of organic electroluminescent device. Drain electrode 116 of transistor is connected electrically with pixel electrodes (the first electrodes) of organic electroluminescent device. In the case of top emission configuration, it is necessary for metal reflecting back light to be used as pixel electrodes.

Drain electrode 116 of thin film transistor 120 is connected with pixel electrodes (the first electrodes) of organic electroluminescent device by connection electric wiring. Connection electric wiring is formed in contact hole 118 penetrating through planarizing layer 117.

For material of planarizing layer 117, inorganic materials such as SiO₂, spin-on-glass, SiN (Si₃N₄), TaO (Ta₂O₅) and organic materials such as polyimide resin, acrylic resin, photoresist material, black matrix material can be used. Spin coating, CVD and evaporation method can be selected depending on these materials. A photosensitive resin is used as a planarizing layer if necessary, and, by procedure of photolithography, contact hole 118 is formed. Or after having formed a planarizing layer on a whole area, contact hole 118 is formed by dry etching or wet etching in position corresponding to lower thin film transistor 120. Contact hole is buried by conductive material. And, the contact hole is connected with pixel electrodes on a planarizing layer. A planarizing layer should be able to cover up TFT, capacitor, electric wiring. Thickness of the planarizing layer should be several μm, and, by way of example only, it is about 3 μm.

The first electrode is comprised on a substrate. When the first electrode is anode, the following material can be used: metal complex oxide such as ITO (indium tin complex oxide), IZO (indium zinc complex oxide), stannic oxide, zinc oxide, indium oxide and zinc aluminium complex oxide; metallic substances such as gold, platinum, chromium; and a layer stack comprising these materials.

A formation method of the first electrode is explained.

Dry method such as resistance heating evaporation method, electron-beam evaporation technique, reactivity evaporation method, ion plating method and sputtering method can be used depending on the material.

In addition, ITO is preferable for reasons of the follows:

low electrical resistance,

high solvent resistance, and

high translucency (in the case of bottom emission method).

ITO is formed on a glass substrate by sputter method. The first electrode is formed by patterning by photolithography method of ITO.

After having formed a first electrode, partition wall is formed to cover a first electrode edge. Partition wall has to have insulating property. By reason of the formation of partition wall, photosensitive materials can be used.

A positive type and negative type can be used as a photosensitive material. Light hardening resins such as photo radical polymerization system, photo cation cure corollary or copolymer containing acrylonitrile composition, poly vinylphenol, polyvinyl alcohol, novolac resin, polyimide resin and cyanoethyl pullulan can be used. In addition, as formation material of partition wall, SiO₂ and TiO₂ can be used.

When formation material of partition wall is a photosensitive material, solution of formation material is coated by slit coat method or spin coating method entirely.

And patterning is performed by photolithography method including exposure process and development process. In the case of spin coating method, height of partition wall can be controlled under conditions of rotation number. However, only by one coating, height of partition wall is limited. If spin-coating process is repeated more than once, partition wall of height more than limited height is able to be formed.

When partition wall is formed by photolithography method using a photosensitive material, configuration of partition wall is controlable by exposure condition and development condition. Example is described below. A photosensitive resin of negative type is used. By exposure, development and post-bake, partition wall is formed. Configuration of a partition wall end is taper configuration. Development conditions such as a kind, density, temperature of a photographic developer or developing time should be controlled to form the partition wall. When condition of development is mild, the following partition wall is formed. Configuration of a partition wall end is taper configuration. On the contrary, when development condition is strong, the following partition wall is formed. Configuration of a partition wall end is inverse configuration of taper configuration.

In addition, when formation material of partition wall is SiO₂ or TiO₂, partition wall can be formed by dry method such as sputtering method or chemical vapor deposition. For this case, patterning of partition wall can be performed by mask or photolithography method.

Organic luminescent media layer is formed next. Organic luminescent media layer may consist of single organic luminous layer. The organic luminescent media layer may have the luminescent assistance layer such as a hole transport layer, a hole injection layer, an electron transport lay and an electron injection layer, other than organic luminous layer.

In addition, a hole transport layer, a hole injection layer, an electron transport layer or an electron injection layer are selected appropriately as necessary. Even if the organic luminescent media layer is single-layered configuration or a layered structure, film thickness of the organic luminescent media layer is lower than 1,000 nm. Preferably it is 50 nm-150 nm.

Here, an embodiment of the organic luminescent media layer of 2 layer structure of a hole transport layer and an organic luminous layer is written down.

Example of a hole transport material comprising a hole transport layer is described below:

copper phthalocyanine, metallophthalocyanine such as tetra(t-butyl)copper phthalocyanine, metal-free phthalocyanine, quinacridon chemical compound, aromatic amine type low molecular hole injection transportation material such as N,N′-di(1-naphthyl)-N,N′-diphenyl-1,1′-biphenyl-4,4′-diamine, 1,1-bis(4-di-p-tolylamino phenyl)cyclohexane, N,N′-diphenyl-N,N′-bis(3-methylphenyl)-1,1′-biphenyl-4,4′-diamine, macromolecule hole transport materials such as polyaniline (PANI), polythiophene, polyvinylcarbazole, mixture with poly(3,4-ethylenedioxy thiophene) (PEDOT) and polystyrene sulfonate, polythiophene oligomer material and other existing hole transport materials.

A hole transport layer can be formed by dry method such as evaporation method or sputter method, and wet method. As wet method, application method such as spin coat method, die coat method, dip coat method, ejection coat method, pre-coat method, roll coat method, bar coat method and printing methods such as relief printing, ink jet printing method, offset printing, gravure printing method are exemplified.

When a hole transport layer is formed by a printing method, a printing process of the present invention can be used.

Before a hole transport layer is formed by wet method, hole transport ink is made. Hole transport ink is made by means of dissolving hole transport material with solvent.

The following solvent can be used:

toluene, dimethylbenzene, acetone, methyl ethyl ketone, methyl isobutyl ketone, cyclohexanone, methanol, ethanol, isopropyl alcohol, ethyl acetate, butyl acetate, water or these combined solvent are exemplified.

Water or alcohols are especially preferred.

Organic luminous layer is the layer which emits light when electric current flows.

The following material can be used as organic luminescent material of organic luminous layer.

The following low molecular type luminescent material can be used:

9,10-diaryl anthracenes, pyrene, coronene, perylene, rubrene, 1,1,4,4-tetra phenylbutadiene, tris(8-hydroxyquinolonate)aluminium complex, tris(4-methyl-8-hydroxyquinolonate)aluminium complex, bis(8-hydroxyquinolonate)zinc complex, tris(4-methyl-5-trifluoromethyl-8-hydroxyquinolonate)aluminium complex, tris(4-methyl-5-cyano-8-hydroxyquinolonate)aluminium complex, bis(2-methyl-5-trifluoromethyl-8-quinolinolate) [4-(4-cyanophenyl)phenolate]aluminium complex, bis(2-methyl-5-cyano-8-quinolinolate) [4-(4-cyanophenyl)phenolate]aluminium complex, tris(8-quinolinolate)scandium complex, bis[8-(para-tosyl)aminoquinoline]zinc complex and cadmium complex, 1,2,3,4-tetraphenylcyclopentadiene and poly-2,5-diheptyloxi-para-phenylenevinylene.

In addition, the material which scattered the following low molecular type luminescent material in a polymeric material can be used: coumarin corollary fluorescent substance, perylene corollary fluorescent substance, pyran type fluorescent substance, anthrone corollary fluorescent substance, porphyrin corollary fluorescent substance, quinacridon corollary fluorescent substance, N,N′-dialkyl displacement quinacridon corollary fluorescent substance, naphthalimido corollary fluorescent substance, N,N′-diaryl displacement pyrrolo pyrrole series fluorescent substance and phosphorescence fluor such as Ir chelate. Polystyrene, polymethyl methacrylate and polyvinylcarbazole can be used as a polymeric material.

In addition, the following macromolecule luminescent material can be used: poly(2-decyloxy-1,4-phenylene) (DO-PPP), poly[2,5-bis-[2-(N,N,N-triethylammonium)ethoxy]-1,4-phenyl-alt-1,4-phenylene] a dibromide (PPP-NEt3+), poly[2-(2′-ethyl hexyloxy)-5-methoxy-1,4-phenylenevinylene] (MEH-PPV), poly[5-methoxy-(2-propanoxysulfide)-1,4-phenylenevinylene] (MPS-PPV), poly[2,5-bis-(Hexyloxy)-1,4-phenylene-(1-cyano vinylene)] (CN-PPV), a polyphenylene vinylene (PPV) derivative such as the above, poly(9,9-dioctyl fluorene) (PDAF) and polyspiro. Macromolecule precursor such as PPV precursor and PPP precursor can be used. In addition, existing luminescent material can be used.

A printing method can be used as a formation method of organic luminous layer. When pattern of organic luminous layer of RGB is formed, organic luminous layer can be formed by a printing method selectively in a pixel part. For this case, organic luminescent ink of each RGB color is used. Therefore, organic electroluminescent device for color display can be produced easily.

By means of dissolving organic luminescent material with solvent, organic luminescent ink is made. As solvent, toluene, dimethylbenzene, acetone, hexane, methyl ethyl ketone, methyl isobutyl ketone, cyclohexanone, methanol, ethanol, isopropyl alcohol, ethyl acetate, butyl acetate, 2-carbinyl-(t-butyl)benzene, 1,2,3,4-tetra methylbenzene, pentyl benzene, 1,3,5-triethylbenzene, cyclohexylbenzene and 1,3,5-tri-isopropyl benzene can be used.

The above described material may be used alone. In addition, the above described material is mixed, and it may be used.

Aromatic hydrocarbon is preferable.

In addition, detergent, antioxidant, viscosity modifier and UV absorber may be added in organic luminescent ink if necessary.

Organic luminous layer is formed by a printing method with the use of organic luminescent ink and printing plate. As a printing method with the use of printing plate, relief printing and offset printing are exemplified.

As offset printing, intaglio offset printing and a printing method as referred to as inversion offset printing are exemplified. Intaglio offset printing and inversion offset printing are explained below.

Ink patternized on blanket having smooth rubber layer is transferred to a substrate.

These printing methods are different in patterning process of ink.

Intaglio offset printing is known as offset printing. Ink is supplied on an intaglio from an ink feed means. By means of filling concavity of an intaglio with ink, ink is patternized. Patternized ink in concavity of an intaglio is transferred to blanket. Blanket is pressed to a substrate. A blanket leaves substrate. Ink pattern on blanket is printed on a substrate.

Inversion offset printing is explained below.

By means of an ink feed means, ink is applied to blanket. The relief printing plate that a convex part is negative pattern is pushed to a blanket. Relief printing plate leaves blanket. Ink of negative pattern is removed from blanket. Desired ink pattern is formed on blanket. A blanket is pressed on substrate. A blanket leaves a substrate. Ink pattern on blanket is printed on a substrate.

In both offset printing, when ink is printed on a substrate, blanket is used.

A blanket used for transfer of ink should be elastic. Generally a blanket made of rubber is used. As for the type of rubber used as a blanket, there are various rubbers such as olefinic type or silicone type. All these rubber have a property that is easy to be swelled and modified against aromatic type organic solvent such as a toluene and dimethylbenzene.

According to the present invention, when organic luminous layer is formed by organic luminescent ink, water development type relief printing plate can be used. Water development type relief printing plate is the relief printing plate that a convex part is formed by water development. Relief printing is explained below.

Ink is supplied to the relief printing plate that configuration of a convex part is a printed pattern. Ink on the convex part is printed on a substrate.

Type of a water development type photosensitive resin comprising printing plate in the present invention is described below. Type comprising hydrophilic polymer, principal monomer so-called cross-linkable monomer including unsaturated bonding, photoinitiator can be used. Polyamide, polyvinyl alcohol, a cellulose derivative are used as hydrophilic polymer of this type. For example, methacrylate having vinyl bonding can be used as cross-linkable monomer. For example, aromatic carbonyl compound can be used as photoinitiator.

Above all, a water development type photosensitive resin of polyamide system is preferred in an aspect of printability.

Organic luminescent ink used in process of manufacture of an organic electroluminescent device of the present invention includes organic solvent.

Solubility parameter (the following, SP value) of a toluene representing organic solvent of particularly preferred aromatic type is 8.9, and SP value of dimethylbenzene is 8.8.

As opposed to these, SP value of polyamide (nylon) is 13.6, and SP value of polyvinyl alcohol is 12.6, and SP value of cellulose is 15.7.

It is found that a water development type photosensitive resin comprising these hydrophilic polymer has enough resistance properties for a toluene, dimethylbenzene because SP value of polyamide, polyvinylalcohol and the like is separated from SP value of toluene or dimethylbenzene enough.

Expansion coefficient of this water development type relief printing plate when it is dipped in a toluene or dimethylbenzene for 24 hours is less than 5%. Thus, swelling and modification of relief printing plate are reduced when organic luminous layer is printed by relief printing method consecutively for a long time. So, a desired pattern can be obtained.

Relief printing apparatus to print on a flat plate can be used as printer for the formation of organic luminous layer. Printer as shown in the following is desirable.

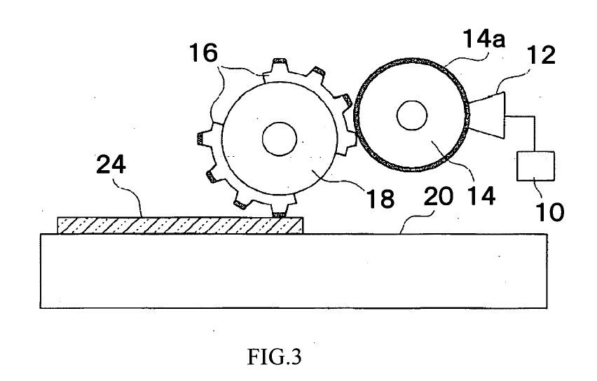

A schematic illustration of relief printing device of the present invention is shown in FIG. 3.

This printer has ink tank 10, ink chamber 12, anilox roll 14 and plate cylinder 18 which plastic relief printing plate 16 is put on. Organic luminescent ink diluted with solvent is taken to ink tank 10. Organic luminescent ink is sent into ink chamber 12 from ink tank 10. Anilox roll 14 contacts with ink feed section of ink chamber 12, and it is supported rotatably.

With rotation of anilox roll 14, thickness of ink layer 14a of organic luminescent ink supplied in anilox roll surface from ink chamber 12 becomes uniform. The ink of this ink layer is transferred on a convex part of relief printing plate 16 carried by plate cylinder 18 rotationally driven in proximity to anilox roll. Even more particularly, patterning of ink is done on position of substrate 24 in stage 20.

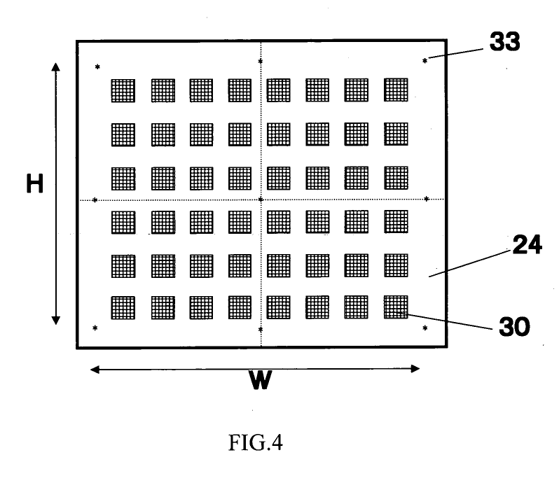

According to the present invention, printing is performed on a substrate divided into plural domain. A profile plane view of a substrate was shown in FIG. 4. (W: the length of one side of the substrate, H: the length of the other side of the substrate.)

In FIG. 4, the example that a lot of organic electroluminescent display units 30 comprising organic electroluminescent device were formed on one substrate is shown. The number of organic electroluminescent display units 30 is 48 (6*8). A substrate is divided by dotted line. The number of domain divided by dotted line is 4. Each domain is printed. In addition, alignment marks 33 for aligning are installed in a substrate.

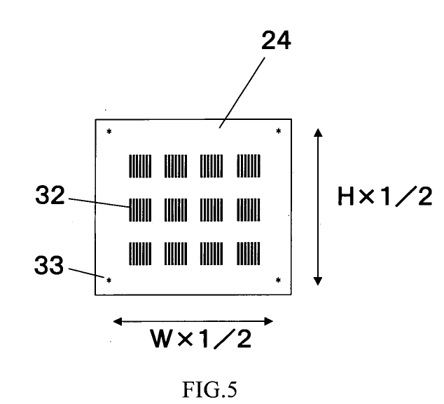

In FIG. 5, a profile plane view of relief printing plate to form organic luminous layer by relief printing on a substrate shown in FIG. 4 was shown. In FIG. 5, size of relief printing plate is ¼ domain of a substrate. Twelve printing patterns 32 are installed in relief printing plate.

At first aligning is performed. Alignment marks 33 formed on a substrate are read by means of charge-coupled device camera. Alignment marks 33 are matched with a marker in a monitor. Printing is performed next.

After this printing, the next print zone is printed. Alignment marks 33 are matched with a printing starting point of the next print zone. Printing is performed afterwards.

And this process is repeated.

Printing is performed sequentially in a divided print zone.

Printing is performed on the whole substrate.

Organic luminous layer is formed in this way.

When organic luminous layer is formed by a printing method, plastic plate is used in relief printing method. Rubber blanket is used in offset printing.

These materials transform by solvent in organic luminescent ink.

Deformation volume of plastic plate or blanket is in proportion to size of plastic plate or blanket.

Thus, pitch accuracy when organic luminescent ink is printed on a substrate falls if size of plastic plate or blanket is large.

According to the present invention, plastic plate and blanket do not have to be large when organic luminescent ink is printed on a large substrate. Therefore, pitch accuracy of formed organic luminous layer does not fall. High minute organic luminescent pattern can be obtained.

Second electrode is formed next.

When second electrode is cathode, the following material is used.

The material that electron injection efficiency is high is used.

By way of example only, metal simple substances such as Mg, Al, Yb are used as the second electrode.

In addition, the following layer stack may be put in a boundary surface of the luminescent medium. The layer stack consists of chemical compound of about 1 nm thicknesses such as Li and oxidation Li, LiF, and Al and Cu which is stable and high conductive.

On the other hand, stability should be balanced with electron injection efficiency. Therefore the following alloy system may be used. Alloy of more than one kind of metal such as Li, Mg, Ca, Sr, La, Ce, Er, Eu, Sc, Y, Yb that a work function is low, and metallic element such as Ag, Al, the Cu which are stable. By way of example only, alloy such as MgAg, AlLi, CuLi can be used.

It is desirable to select a material having translucency in so-called top emission construction that visible radiation comes out of the second electrode side.

By way of example only, rarefaction by assembly of these metal and clear electrically conducting layer such as ITO is enabled.

As a formation method of second electrode, dry process method such as resistance heating evaporation method, electron-beam evaporation technique, reactivity evaporation method, ion plating method and sputtering method can be used depending on the material. In addition, patterning can be done by masks when patterning of second electrode is necessary. As for the thickness of second electrode, 10 nm-1,000 nm are preferable.

In addition, first electrode may be cathode in the present invention. Second electrode may be anode.

As organic electroluminescent device, organic luminous layer is sandwiched between electrodes, and it can emit light by applied electric current. However, organic luminous layer, organic luminous media layer and some of electrode deteriorate easily by means of atmospheric moisture and oxygen. Thus a seal to intercept organic luminous layer and the like from the outside is usually provided.

A sealing body is explained below.

By way of example only, the substrate that first electrode, the organic luminescent media layer including organic luminous layer and second electrode are formed is prepared. Resin layer is provided over a sealing medium. A sealing medium is stuck on a substrate by means of resin layer.

For a sealing medium, it is necessary for transmissivity of moisture and oxygen to be low.

In addition, as an example of material of the sealing medium, ceramics such as alumina, silicon nitride, boron nitride, glass such as no-alkali glass, alkali glass, quartz, metallic foil such as aluminium or stainless, humidity resistance film are exemplified.

By way of example only, the following humidity resistance film is exemplified:

The film which is formed SiOx by CVD method on both sides of a plastic substrate; the film which laminated the film that transmissivity of moisture and oxygen is small and hydrophilic film; and the film which water absorption agent was applied on the film that transmissivity of moisture and oxygen is small.

It is preferable for water vapor permeation rate of the humidity resistance film to be less than 10⁻⁶ g/m²/day.

For example, for resin layer, the following material can be used:

A photo-curing adhesive property resin, a heat curing adhesive property resin, 2 fluid hardening adhesive property resins comprising an epoxy type resin, acrylic resin, silicone oil and the like, acrylic resin such as ethylene ethylacrylate (EEA) polymer, vinyl resins such as ethylene vinyl acetate (EVA), thermoplastic resin such as polyamide, a synthetic rubber, thermoplasticity adhesive property resins such as acid denatured substances of polyethylen or polypropylene.

An example of method to form resin layer on a sealing medium is shown below:

solvent solution method, pushing out laminate method, fusion/hot melt method, calender method, discharge jet application method, screen printing, vacuum laminate method and heated roll laminate method.

A material having hygroscopicity and a property to absorb oxygen can be incorporated into adhesive if necessary.

Depending on size and configuration of sealed organic electroluminescent display unit, thickness of resin layer installed in a sealing medium is fixed. As for the thickness of resin layer, about 5-500 μm are desirable.

In a sealing room, a substrate with first electrode, organic luminous media layer including organic luminous layer and second electrode is affixed to a sealing body.

When it is two layers construction consisting of a sealing medium and resin layer of thermoplastic resin, contact bonding should be performed only by heating roller.

In the case of a heat curing type adhesion resin, it attaches by pressure by heating roller. And a heat curing type adhesion resin is heated, and is hardened.

At first, in the case of a photo-curing-related adhesion resin, it is sealed by pressure by roller. And a photo-curing-related adhesion resin is stiffened by irradiating a light.

In addition, in the above described example, resin layer was formed on a sealing medium. However, after having formed resin layer on a substrate, it may be stuck with a sealing medium.

Before sealing by means of a sealing body, inorganic thin film may be formed. By way of example only, as passivation film, silicon-nitride film of film thickness of 150 nm is formed by CVD method. In addition, a sealing body consisting of inorganic thin film can be formed.

In addition, a glass cap and a metal cap having a concavity are used, and it can be sealed. A top face of second electrode corresponds to the concavity. About the penumbra, the cap and the substrate are adhered.

### EFFECT OF THE INVENTION

According to the current invention, when a lot of organic electroluminescent device is formed in a large-scale substrate, without influence of modification of plastic plate and blanket, printing of high accuracy is possible.

In invention concerning claim 1, the organic electroluminescent device that total pitch accuracy is equal to or less than plus or minus 20 μm is made in a substrate which is larger than 500 mm square size by existing relief printing or offset printing.

By way of example only, manufacture of organic electroluminescent device was enabled on a substrate of 800 mm square size.

In invention concerning claim 2, manufacture of high minute organic electroluminescent device was enabled by forming the organic luminous layer that it was necessary to be painted in separated three colors of RGB.

In offset printing, ink is attached to the printing plate that pattern is formed. The ink is transferred to blanket having elasticity. Next, ink on blanket is transferred to substrate. It is required that blanket has elasticity. Generally blanket is made of rubber. A kind of rubber is olefinic system or silicone system. Both rubber is easy to swell by aromatic hydrocarbon such as toluene or dimethylbenzene used as solvent.

In invention concerning claim 3, because water development type relief printing plate is used, modification of relief printing plate by solvent comprising organic luminescent ink is reduced. Therefore, a pattern printing is possible.

In invention concerning claim 4, a manufacturing method of the organic electroluminescent device that total pitch accuracy is high can be provided in spite of printing by printing plate comprising contraction and expansion properties material.

The organic electroluminescent device that total pitch accuracy was high was able to be provided with invention concerning claim 5. For example, total pitch accuracy is equal to or less than plus or minus 20 μm.

### EXAMPLE 1

Organic electroluminescent device of passive matrix method was made by application liquid for organic electroluminescence.

As shown in FIG. 4, organic electroluminescent device was produced to form forty-eight organic electroluminescent display units on a glass substrate of 550 mm*650 mm. An organic electroluminescent display resolution is 64*64 pixels.

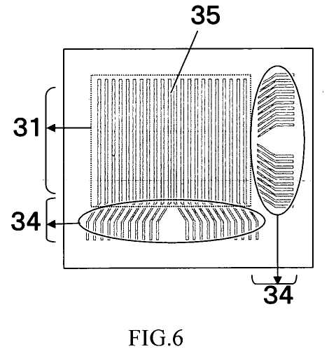

At first ITO line of 200 μm pitch (L/S=160/40) was made for a translucency substrate. As for the ITO line, thickness was 150 nm. The number of ITO line was 192. ITO line was anode. A figure of ITO anode pattern in an organic electroluminescent display unit is shown in FIG. 6. ITO anode pattern 35 consists of luminescent pixel areas 31 and wired connection parts 34.

Insulating property regist was provided afterwards. Partition wall was formed by photolithography method. Partition wall covers an ITO end. A most thickness part of partition wall is 1.2 μm.

UV/O₃ cleaning was performed successively.

1 wt % water dispersion solution of poly(3,4-ethylenedioxy thiophene) presented in (chemical formula 1) and polystyrene sulfonate (PEDOT/PSS) was applied by slit coat method. Thickness was 80 nm. A hole transport layer was formed in this way.
(Chemical Formula 1)

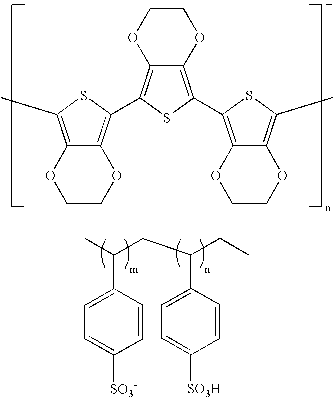

Then subsequently organic luminous layer is explained below.

The RGB3-colored organic luminescent material that macromolecule luminescent material MEH-PPV presented in (chemical formula 2) was a fabric was dissolved in cyclohexylbenzene solution in 1.3 wt %.

Even more particularly, polystyrene (molecular weight Mw1000000, a product made in Aldrich Corporation) was dissolved in 0.26 wt %.

Organic luminescent ink of red (R) green (G) blue (B) was prepared in this way.

A substrate is divided into four domain.

At first organic luminous layer was formed by relief printing method with organic luminescent ink of red (R). Twelve convex part domains comprising display unit line pattern and alignment marks are installed in printing plate. In this formation, film thickness of organic luminous layer was 80 nm.

Even more particularly, printing to every divided domain was performed about green (G) and blue (B).
(Chemical Formula 2)

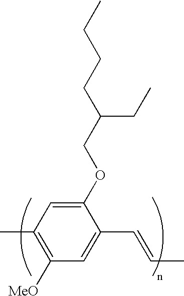

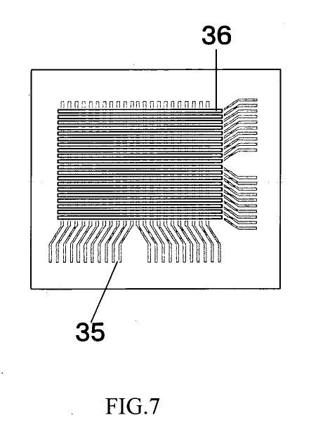

Subsequently a cathode layer was formed. MgAg was formed through a mask by the two-source evaporation method. The thickness was 200 nm. Organic electroluminescent device of passive driving type was made in this way. A figure of pattern of cathode comprising MgAg in an organic electroluminescent display unit was shown in FIG. 7. Cathode pattern 36 was formed to be perpendicular to ITO anode pattern.

Leakage current did not flow to this organic electroluminescent device of passive matrix method. Only a selected pixel was able to be turned on. The luminescence was 100 cd/m² at 5V. The luminescence was uniform.

### COMPARATIVE EXAMPLE 1

A substrate of 550*650 mm size was prepared. Relief printing plate of 570*670 mm size was prepared. Organic luminous layer was printed on a substrate once by this relief printing plate. Forty-eight organic electroluminescent display units can be produced from one substrate. However, relief printing plate was shortened. Therefore line of luminous layer on a substrate penumbra deviated from electrode.

What is claimed is:

1. A manufacturing method of an organic electroluminescent device comprising a substrate, a first electrode on the substrate, a partition wall next to the first electrode, an organic luminous media layer including an organic luminous layer on the first electrode, and a second electrode which faces the first electrode, wherein the organic luminous media layer is sandwiched between the first and the second electrode, the method comprising.
preparing ink, including a material for at least the organic luminous media layer, dissolved in a solvent; and
forming the organic luminous media layer by printing the ink on every divided plural domains of the substrate.

2. The manufacturing method of the organic electroluminescent device according to claim 1, wherein
the organic luminous media layer is an organic luminous layer.

3. The manufacturing method of the organic electroluminescent device according to claim 1, wherein
the printing is relief printing with use of a water development type printing plate.

4. The manufacturing method of the organic electroluminescent device according to claim 1, wherein
a size of at least one of the divided domains is smaller than 500 mm square.

5. An organic electroluminescent device having an organic luminous layer formed by the method according to claim 1.
